(19) United States
(12) Patent Application Publication
(10) Pub. No.: US 2025/0140638 A1
(43) Pub. Date: May 1, 2025

(54) SEMICONDUCTOR DEVICE

(71) Applicant: Mitsubishi Electric Corporation, Tokyo (JP)

(72) Inventor: Nobuchika AOKI, Tokyo (JP)

(73) Assignee: Mitsubishi Electric Corporation, Tokyo (JP)

(21) Appl. No.: 18/810,466

(22) Filed: Aug. 20, 2024

(30) Foreign Application Priority Data
Oct. 30, 2023 (JP) 2023-185707

(51) Int. Cl. H01L 23/367; H01L 23/46

(52) U.S. Cl. CPC H01L 23/3677; H01L 23/46

(57) ABSTRACT

A semiconductor device includes a heat dissipation base member and a plurality of heat dissipation fins. The plurality of heat dissipation fins is joined to a lower surface of the heat dissipation base member. Each of the plurality of heat dissipation fins includes a plurality of crest portions formed by repeatedly bending a band-shaped plate member extending in one direction. The cross-sectional shape of each of the plurality of heat dissipation fins is distorted due to a left-right asymmetric shape of each of the plurality of crest portions. The plurality of crest portions has a sparse region in which an interval between the plurality of crest portions in an extending direction of each of the plurality of heat dissipation fins is sparse and a dense region in which an interval between the plurality of crest portions in the extending direction is denser than the interval in the sparse region.

### BACKGROUND OF THE INVENTION

### Field of the Invention

The present disclosure relates to a semiconductor device.

### Description of the Background Art

In order to dissipate heat generated from a semiconductor element, a semiconductor device including heat dissipation fins has been proposed. For example, Japanese Patent Application Laid-Open No. 2016-82237 discloses a cooling system for an electronic component in which a heat sink element is provided on one surface of a heat exchanger plate. A plurality of loops is formed in the heat sink element, and the plurality of loops has a regular pattern.

In a case where heat dissipation fins have regular shapes, the heat dissipation fins act to uniformly cool the inside of the plane of a heat dissipation base member. Such heat dissipation fins cannot effectively cool a portion locally generating a large amount of heat in a semiconductor device, such as a semiconductor element, a wire bond portion, and a terminal portion.

### SUMMARY

An object of the present disclosure is to provide a semiconductor device that effectively cools a portion that locally generates heat.

A semiconductor device according to the present disclosure includes a heat dissipation base member and a plurality of heat dissipation fins. The heat dissipation base member dissipates heat generated in a semiconductor element. The plurality of heat dissipation fins is joined to a lower surface of the heat dissipation base member and is arranged in parallel with each other. The semiconductor element is held on an upper surface of the heat dissipation base member. Each of the plurality of heat dissipation fins includes a plurality of crest portions formed by repeatedly bending a band-shaped plate member extending in one direction. The cross-sectional shape of each of the plurality of heat dissipation fins is distorted due to a left-right asymmetric shape of each of the plurality of crest portions. The plurality of crest portions has a sparse region in which an interval between the plurality of crest portions in an extending direction of each of the plurality of heat dissipation fins is sparse and a dense region in which an interval between the plurality of crest portions in the extending direction is denser than the interval in the sparse region.

There is provided the semiconductor device that effectively cools a portion that locally generates heat.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment;

FIG. 2 is a bottom view illustrating the configuration of the semiconductor device;

FIGS. 3 to 5 are cross-sectional views each illustrating the configuration of the semiconductor device;

FIG. 6 is a diagram illustrating a temperature distribution inside the semiconductor device according to the first preferred embodiment;

FIG. 7 is a diagram illustrating a temperature distribution inside a semiconductor device in a comparative example;

FIG. 8 is a cross-sectional view illustrating a configuration of a semiconductor device in a first modification of the first preferred embodiment;

FIG. 9 is a cross-sectional view illustrating a configuration of a semiconductor device in a second modification of the first preferred embodiment;

FIGS. 10 and 11 are cross-sectional views each illustrating a configuration of a semiconductor device according to a second preferred embodiment;

FIG. 12 is a bottom view illustrating a configuration of a semiconductor device according to a third preferred embodiment;

FIG. 13 is a cross-sectional view illustrating a configuration of a semiconductor device according to a fourth preferred embodiment;

FIG. 14 is a cross-sectional view illustrating a configuration of a semiconductor device according to a fifth preferred embodiment; and

FIG. 15 is a view illustrating an angle between a lower surface of a heat dissipation base member and a crest portion of a heat dissipation fin.

### DESCRIPTION OF THE PREFERRED EMBODIMENTS

### First Preferred Embodiment

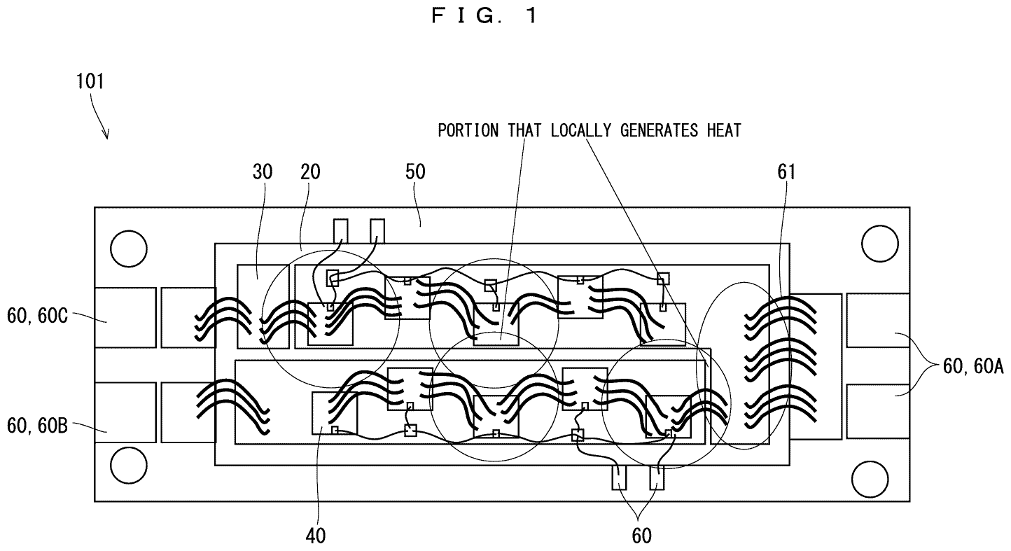

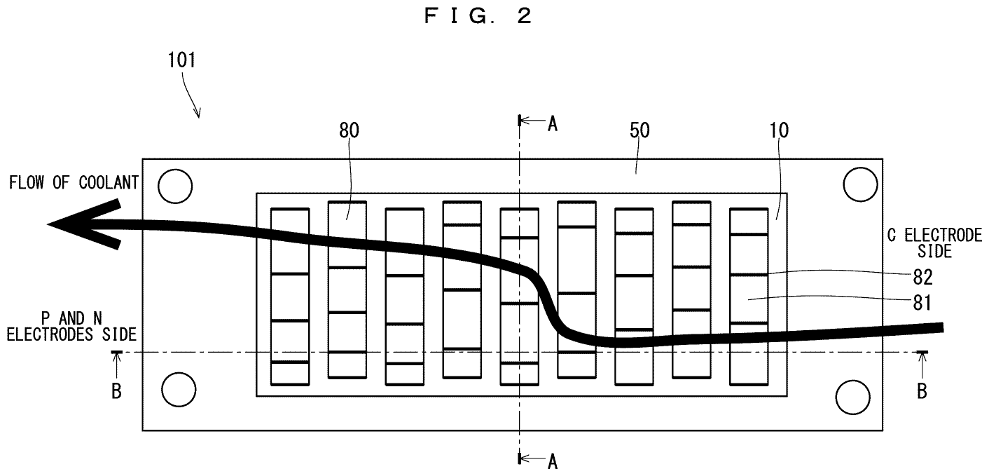

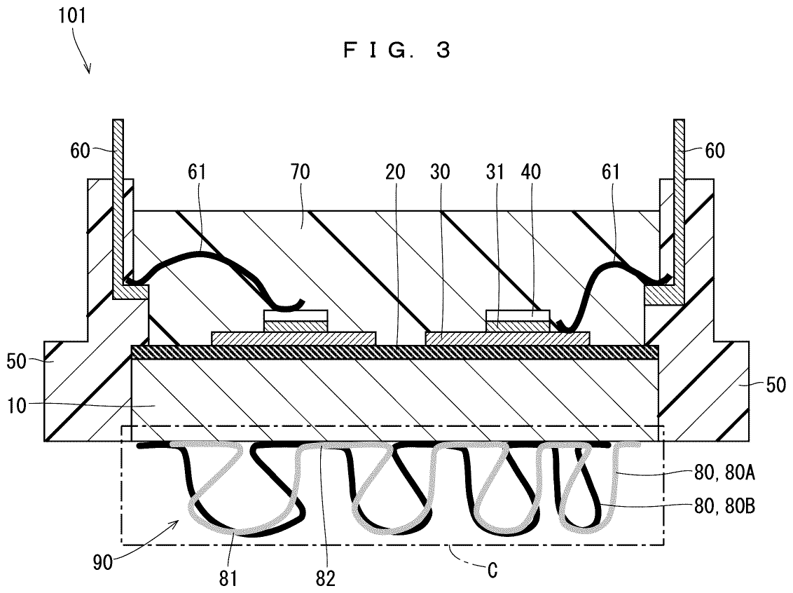

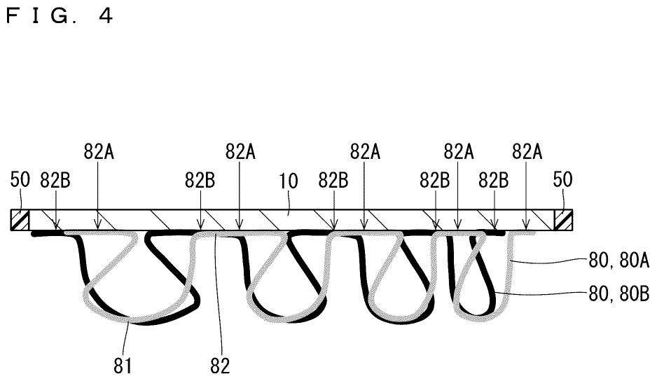

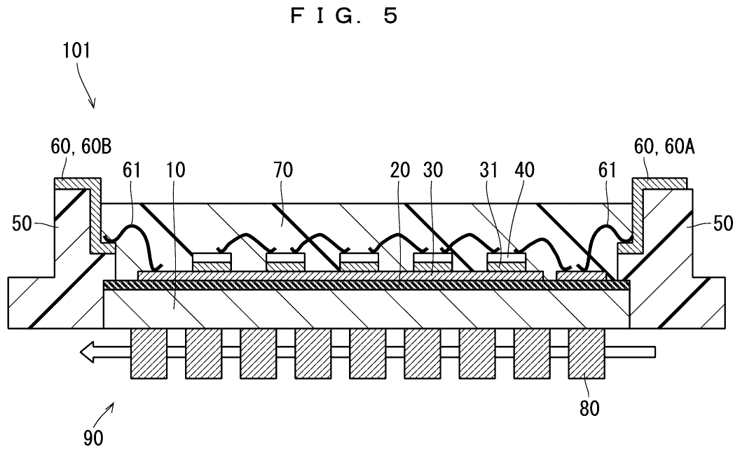

FIG. 1 is a plan view illustrating a configuration of a semiconductor device 101 according to a first preferred embodiment. FIG. 2 is a bottom view illustrating the configuration of the semiconductor device 101. FIGS. 3 to 5 are cross-sectional views illustrating the configuration of the semiconductor device 101. FIG. 3 illustrates a configuration of a cross section taken along line A-A illustrated in FIG. 2. FIG. 4 illustrates a configuration of a region C illustrated in FIG. 3. FIG. 5 illustrates a configuration of a cross section taken along line B-B illustrated in FIG. 2.

The semiconductor device 101 includes a heat dissipation base member 10, an insulating layer 20, a circuit pattern 30, a semiconductor element 40, a case 50, a terminal 60, a sealing material 70, a plurality of heat dissipation fins 80, and a coolant flow path 90.

The heat dissipation base member 10 is, for example, a plate including a metal such as copper or aluminum, or a plate including an AlSiC composite. The heat dissipation base member 10 is also referred to as a heat sink or a base plate. The heat dissipation base member 10 has a function of transmitting heat generated by an electronic component such as the semiconductor element 40 to the outside, that is, a heat dissipation function.

The insulating layer 20 is provided on an upper surface of the heat dissipation base member 10. The insulating layer 20 includes, for example, resin.

The circuit pattern 30 is provided on the upper surface of the heat dissipation base member 10 with the insulating layer 20 interposed therebetween. The circuit pattern 30 includes a conductive material such as metal.

The semiconductor element 40 is provided on the circuit pattern 30 with a joint material 31 interposed therebetween. That is, the semiconductor element 40 is held on the upper surface of the heat dissipation base member 10. The joint material 31 is a conductive material such as solder. The semiconductor element 40 includes, for example, a semiconductor such as Si. The semiconductor is preferably a so-called wide band gap semiconductor such as SiC, GaN, Ga₂O₃, GeO₂, or diamond. The semiconductor element 40 is a power semiconductor element, a control integrated circuit (IC) for controlling the power semiconductor element, or the like. The semiconductor element 40 includes, for example, an insulated gate bipolar transistor (IGBT), a metal oxide semiconductor field effect transistor (MOSFET), a Schottky barrier diode, or the like. Alternatively, the semiconductor element 40 may include a reverse-conducting IGBT (RC-IGBT) in which an IGBT and a freewheeling diode are formed in one semiconductor substrate.

The case 50 has a rectangular frame body in plan view. The case 50 accommodates the heat dissipation base member 10, the insulating layer 20, the circuit pattern 30, and the semiconductor element 40 inside the frame body. The case 50 is disposed so as to surround the outer periphery of the heat dissipation base member 10, and is joined to the heat dissipation base member 10. The case 50 includes, for example, resin.

The terminal 60 is held by the case 50. For example, a plurality of terminals 60 is provided on four sides constituting the frame body of the case 50. As illustrated in FIGS. 3 and 5, the terminals 60 are provided at both ends of the case 50. The terminal 60 is a conductor connectable to an external circuit provided outside the semiconductor device 101. The terminal 60 is, for example, a metal frame obtained by processing a flat plate including metal such as copper into a predetermined shape. The terminal 60 is fixed to the case 50 by embedding a part of the terminal 60 in the case 50. The terminal 60 is electrically connected to the semiconductor element 40. A metal wire 61 is joined to one end of the terminal 60. The metal wire 61 is joined to the circuit pattern 30 or the semiconductor element 40. The terminals 60 include a C electrode 60A, a P electrode 60B, and an N electrode 60C.

The sealing material 70 is filled in a space inside the case 50. The sealing material 70 seals the insulating layer 20, the circuit pattern 30, the semiconductor element 40, a part of the terminal 60, and the metal wire 61. The sealing material 70 includes an insulating and curable resin. The sealing material 70 is, for example, a silicone resin, an epoxy resin, or the like.

The plurality of heat dissipation fins 80 is joined to a lower surface of the heat dissipation base member 10 and is arranged in parallel with each other. The plurality of heat dissipation fins 80 in the first preferred embodiment extends in the lateral direction of the case 50. Each of the plurality of heat dissipation fins 80 includes a plurality of crest portions 81 and a plurality of valley portions formed by repeatedly bending a band-shaped plate member extending in the lateral direction, that is, one direction.

The heat dissipation fins 80 are joined to the lower surface of the heat dissipation base member 10 at a plurality of joint portions 82. The plurality of joint portions 82 is provided at the plurality of valley portions, respectively, that is, between the plurality of crest portions 81. At least one of the plurality of joint portions 82 is located immediately below the semiconductor element 40. Alternatively, at least one of the plurality of joint portions 82 is located immediately below the joint position between the metal wire 61 joined to the terminal 60 and the circuit pattern 30. The metal wire 61 is driven down from the terminal 60, which is one of the C electrode 60A, the P electrode 60B, and the N electrode 60C to the circuit pattern 30.

The plurality of crest portions 81 has a sparse region in which an interval between the crest portions 81 in the extending direction of the heat dissipation fin 80 is sparse and a dense region in which an interval between the crest portions 81 in the extending direction is denser than the interval in the sparse region. For example, in FIGS. 3 and 4, the sparse region is arranged on the left side, and the dense region is arranged on the right side. Although not illustrated, a plurality of sparse regions and a plurality of dense regions may be disposed in one heat dissipation fin 80. The sparse regions and the dense regions are irregularly arranged in one heat dissipation fin 80, for example. Alternatively, the sparse region and the dense region may be disposed at predetermined positions such that a coolant described later intensively flows to a local heat generating portion inside the semiconductor device 101.

The cross-sectional shape of the heat dissipation fin 80 is distorted in one of the left and right directions due to a left-right asymmetric shape of each of the plurality of crest portions 81. As illustrated in FIGS. 3 and 4, in the first preferred embodiment, the plurality of crest portions 81 provided in one heat dissipation fin 80 is distorted in the same direction, but may be distorted irregularly in directions different from each other.

As illustrated in FIG. 4, among the plurality of heat dissipation fins 80, a first heat dissipation fin 80A and a second heat dissipation fin 80B are shifted from each other in joint positions (for example, the center positions of the joint portions 82) with the lower surface of the heat dissipation base member 10 in the extending direction. In other words, the position of the joint portion 82A of the first heat dissipation fin 80A in the extending direction is shifted from the position of the joined portion 82B of the second heat dissipation fin 80B in the extending direction. In the first preferred embodiment, the position of the joint portion 82 in the extending direction is different for each of the heat dissipation fins 80. The first heat dissipation fin 80A and the second heat dissipation fin 80B are arbitrary heat dissipation fins among the plurality of heat dissipation fins 80. For example, the first heat dissipation fin 80A is a heat dissipation fin in a first row, and the second heat dissipation fin 80B is a heat dissipation fin in a second row.

The coolant flow path 90 is provided on the lower surface of the heat dissipation base member 10 so as to include the plurality of heat dissipation fins 80. A coolant for cooling the heat dissipation fins 80 flows through the coolant flow path 90. The coolant in the first preferred embodiment flows in a direction from the C electrode 60A toward the P electrode 60B or the N electrode 60C. The heat dissipation fin 80 extends in a direction intersecting with the direction in which the coolant flows. For example, the heat dissipation fin 80 extends in a direction orthogonal to the direction in which the coolant flows.

In a case where the joint portions 82 are located immediately below the semiconductor element 40 and immediately below the joint position between the metal wire 61 and the circuit pattern 30, heat generated inside the semiconductor device 101 is efficiently transferred to the heat dissipation fin 80. The sparse region and the dense region of the plurality of crest portions 81 are disposed at predetermined positions according to the local heat generating portion. Therefore, the coolant intensively flows to the heat generating portion. As a result, the cooling effect is improved.

In addition, the cross-sectional shape of the heat dissipation fin 80 is distorted, and the joint positions in the extending direction are different for each heat dissipation fin 80. Such a configuration causes slight turbulence in the coolant. This turbulence improves the heat dissipation effect in the heat dissipation fins 80. Even if the joint positions in the extending direction are the same among the heat dissipation fins 80, the cross-sectional shapes of the heat dissipation fins 80 are distorted, so that turbulence occurs. In order to generate larger turbulence, it is preferable that the joint positions in the extending direction are different for each of the heat dissipation fins 80.

When the semiconductor device 101 is driven, a current continues to flow through the C electrode 60A at all times. Therefore, heat generation at the joint position of the metal wire 61 driven down from the C electrode 60A to the circuit pattern 30 increases. Since the coolant cooled by a chiller flows in from the C electrode 60A side, the heat generated around the C electrode 60A is effectively cooled.

To summarize the above, the semiconductor device 101 according to the first preferred embodiment includes the heat dissipation base member 10 and the plurality of heat dissipation fins 80. The heat dissipation base member 10 dissipates heat generated in the semiconductor element 40. The plurality of heat dissipation fins 80 is joined to the lower surface of the heat dissipation base member 10 and is arranged in parallel with each other. The semiconductor element 40 is held on the upper surface of the heat dissipation base member 10. Each of the plurality of heat dissipation fins 80 includes the plurality of crest portions 81 formed by repeatedly bending a band-shaped plate member extending in one direction. The cross-sectional shape of each of the plurality of heat dissipation fins 80 is distorted due to a left-right asymmetric shape of each of the plurality of crest portions 81. The plurality of crest portions 81 has a sparse region in which an interval between the crest portions 81 in the extending direction of each of the plurality of heat dissipation fins 80 is sparse and a dense region in which an interval between the crest portions 81 in the extending direction is denser than the interval in the sparse region.

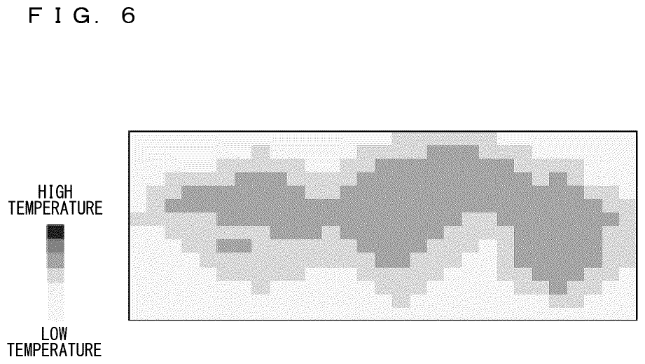

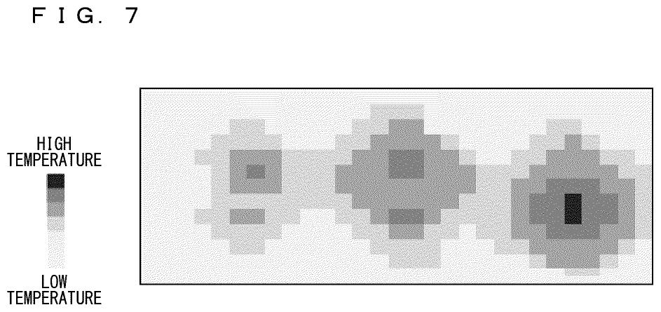

FIG. 6 is a diagram illustrating a temperature distribution inside the semiconductor device 101 according to the first preferred embodiment. FIG. 7 is a diagram illustrating a temperature distribution inside a semiconductor device in a comparative example. The semiconductor device 101 effectively cools a portion that locally generates heat. In other words, local heat generation inside the semiconductor device 101 is suppressed. Such a configuration realizes miniaturization and densification of the semiconductor device 101.

In a case where the semiconductor element 40 includes a wide band gap semiconductor, the semiconductor element 40 is miniaturized. Such a configuration realizes further miniaturization and densification of the semiconductor device 101.

### First Modification of First Preferred Embodiment

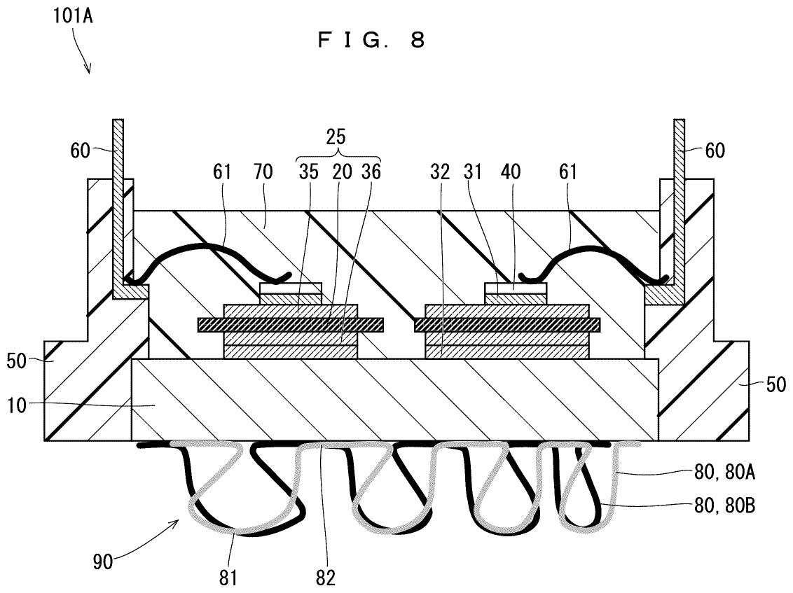

FIG. 8 is a cross-sectional view illustrating a configuration of a semiconductor device 101A in a first modification of the first preferred embodiment. Similarly to FIG. 3, FIG. 8 illustrates a configuration of a cross section taken along line A-A illustrated in FIG. 2.

The semiconductor device 101A includes an insulating substrate 25. The insulating substrate 25 is joined to an upper surface of the heat dissipation base member 10 with a joint material 32 interposed therebetween. The insulating substrate 25 includes an insulating layer 20, a front-surface circuit pattern 35, and a back-surface circuit pattern 36. The insulating layer 20 includes, for example, ceramic. The front-surface circuit pattern 35 is provided on an upper surface of the insulating layer 20. The back-surface circuit pattern 36 is provided on a lower surface of the insulating layer 20. The front-surface circuit pattern 35 corresponds to the circuit pattern 30 described in the first preferred embodiment. Even with such a configuration, effects similar to those of the first preferred embodiment can be obtained.

### Second Modification of First Preferred Embodiment

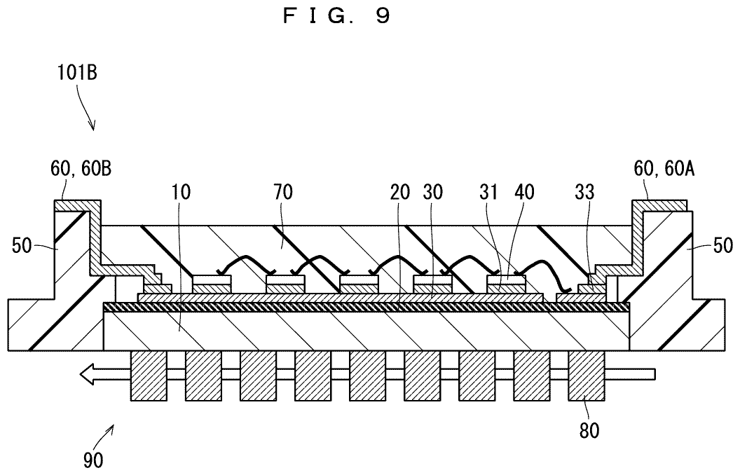

FIG. 9 is a cross-sectional view illustrating a configuration of a semiconductor device 101B in a second modification of the first preferred embodiment. Similarly to FIG. 5, FIG. 9 illustrates a configuration of a cross section taken along line B-B illustrated in FIG. 2.

The C electrode 60A and the P electrode 60B as the terminals 60 are joined to the circuit pattern 30 by a joint material 33 instead of the metal wire 61. The terminals 60 may be directly joined to the circuit pattern 30. At least one of the plurality of joint portions 82 of the heat dissipation fin 80 is located immediately below the joint position between the terminal 60 and the circuit pattern 30. Even with such a configuration, effects similar to those of the first preferred embodiment can be obtained.

### Second Preferred Embodiment

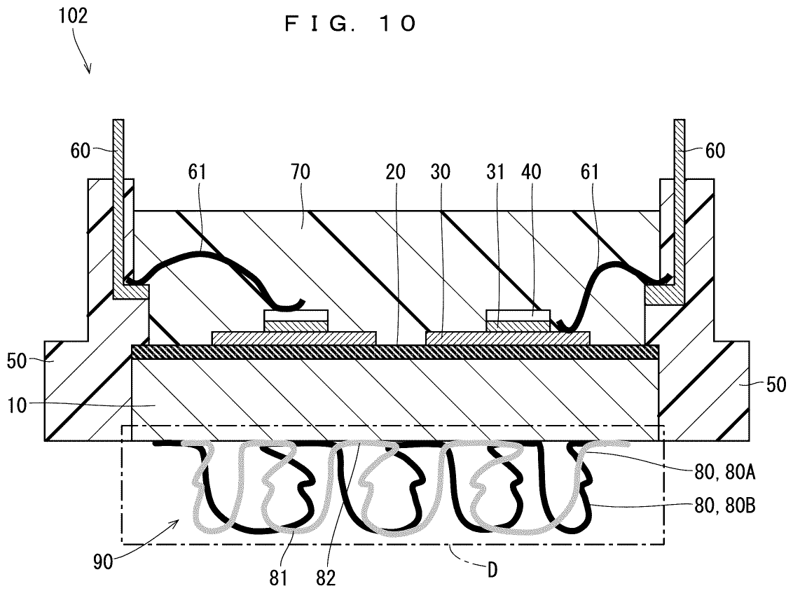

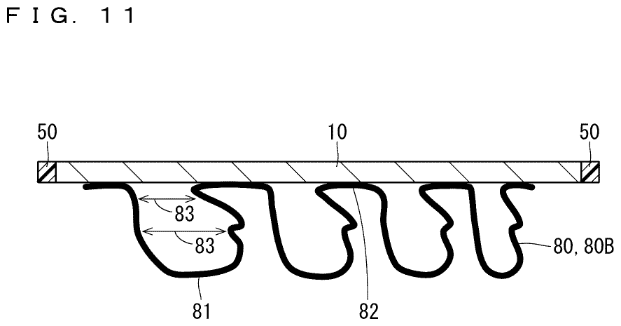

In a second preferred embodiment, components similar to those in the first preferred embodiment are denoted by the same reference signs, and the detailed description thereof will be omitted. FIGS. 10 and 11 are cross-sectional views illustrating a configuration of a semiconductor device 102 according to the second preferred embodiment. FIG. 11 illustrates a configuration of a region D illustrated in FIG. 10. FIG. 11 illustrates only a cross section of a second heat dissipation fin 80B among a plurality of heat dissipation fins 80.

Each of a plurality of crest portions 81 of the heat dissipation fin 80 includes two or more constricted portions 83. The increase in the surface area of the heat dissipation fin 80 improves the cooling capacity of the heat dissipation fin 80. The semiconductor device 102 of the second preferred embodiment is more efficiently cooled than the semiconductor device 101 of the first preferred embodiment. Such a configuration realizes miniaturization and densification of the semiconductor device 102.

### Third Preferred Embodiment

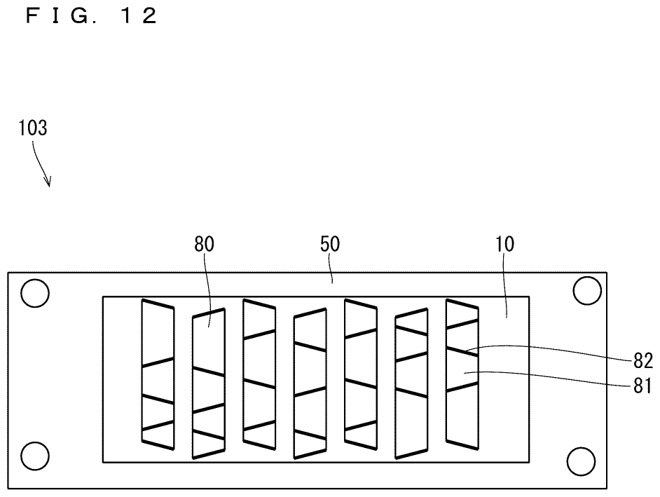

In a third preferred embodiment, components similar to those in the first or second preferred embodiment are denoted by the same reference signs, and the detailed description thereof will be omitted. FIG. 12 is a bottom view illustrating a configuration of a semiconductor device 103 according to the third preferred embodiment.

A plurality of joint portions 82 joining a heat dissipation fin 80 and a heat dissipation base member 10 between crest portions 81 has a chevron shape (V-shape) in plan view. The flow of coolant is complicated, so that larger turbulence occurs. As a result, the cooling effect is improved. With such a configuration, for example, the cooling effect is improved as compared with the semiconductor device 101 of the first preferred embodiment, and further, miniaturization and densification of the semiconductor device 103 are realized. The chevron-shaped joint portions 82 are applicable not only to the semiconductor device 101 but also to the semiconductor device 102.

### Fourth Preferred Embodiment

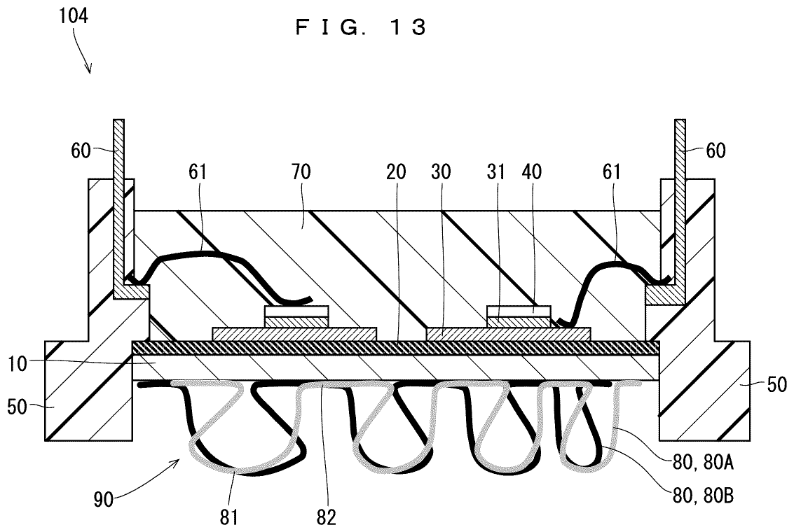

In a fourth preferred embodiment, components similar to those in any one of the first to third preferred embodiments are denoted by the same reference signs, and the detailed description thereof will be omitted. FIG. 13 is a cross-sectional view illustrating a configuration of a semiconductor device 104 according to the fourth preferred embodiment.

A lower surface of a heat dissipation base member 10 is recessed from a back surface of a case 50. Heat dissipation fins 80 are disposed in the recess, and a coolant flow path 90 is formed therein. Such a configuration achieves a reduction in size and height, and an increase in density as compared with the semiconductor device 101 according to the first preferred embodiment, while having a cooling effect equivalent to that of the semiconductor device 101, for example. Furthermore, such a configuration can be applied not only to the semiconductor device 101 but also to both the semiconductor device 102 and the semiconductor device 103.

### Fifth Preferred Embodiment

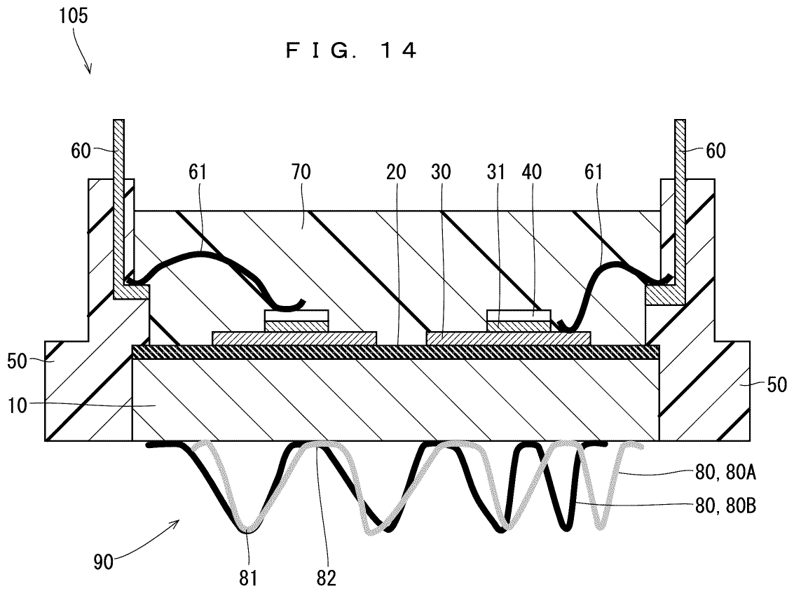

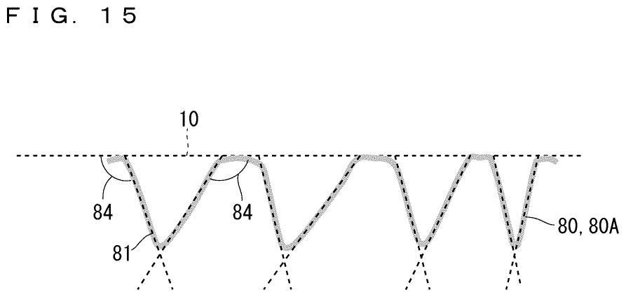

In a fifth preferred embodiment, components similar to those in any one of the first to fourth preferred embodiments are denoted by the same reference signs, and the detailed description thereof will be omitted. FIG. 14 is a cross-sectional view illustrating a configuration of a semiconductor device 105 according to the fifth preferred embodiment. FIG. 15 is a view illustrating an angle between a lower surface of a heat dissipation base member 10 and a crest portion 81 of a heat dissipation fin 80. FIG. 15 illustrates only a cross section of a first heat dissipation fin 80A among a plurality of heat dissipation fins 80.

At least one of two external angles 84 formed by the lower surface of the heat dissipation base member 10 and one crest portion 81 is 90° or more. In a case where both the external angles 84 are 90° or more and the cross-sectional shape of the crest portion 81 is approximately triangular, the strength of the heat dissipation fin 80 against external force increases. In particular, the strength against external force in a direction from directly below the heat dissipation base member 10 increases. Since the flow rate of a coolant can be increased as compared with the semiconductor device 101 of the first preferred embodiment, the cooling effect is improved. Such a configuration realizes miniaturization and densification of the semiconductor device 105. Further, the configuration of the third preferred embodiment or the configuration of the fourth preferred embodiment may be applied to the semiconductor device 105. FIGS. 14 and 15 illustrate an example in which both the external angles 84 are 90° or more, but only one of the external angles may be 90° or more.

In the present disclosure, the preferred embodiments can be freely combined, and the preferred embodiments can be appropriately modified or omitted.

Hereinafter, various aspects of the present disclosure will be collectively described as appendixes.

### Appendix 1

A semiconductor device comprising:
a heat dissipation base member which dissipates heat generated in a semiconductor element; and
a plurality of heat dissipation fins which is joined to a lower surface of the heat dissipation base member and is arranged in parallel with each other,
wherein
the semiconductor element is held on an upper surface of the heat dissipation base member,
each of the plurality of heat dissipation fins includes a plurality of crest portions formed by repeatedly bending a band-shaped plate member extending in one direction,
a cross-sectional shape of each of the plurality of heat dissipation fins is distorted due to a left-right asymmetric shape of each of the plurality of crest portions, and
the plurality of crest portions have a sparse region in which an interval between the plurality of crest portions in an extending direction of each of the plurality of heat dissipation fins is sparse and a dense region in which an interval between the plurality of crest portions in the extending direction is denser than the interval in the sparse region.

### Appendix 2

The semiconductor device according to Appendix 1, wherein among the plurality of heat dissipation fins, a first heat dissipation fin and a second heat dissipation fin are shifted from each other in joint positions with the lower surface of the heat dissipation base member in the extending direction.

### Appendix 3

The semiconductor device according to Appendix 1 or 2, wherein the sparse region and the dense region of the plurality of crest portions are irregularly arranged.

### Appendix 4

The semiconductor device according to any one of Appendixes 1 to 3, wherein
each of the plurality of heat dissipation fins is joined to the lower surface of the heat dissipation base member at a plurality of joint portions provided between the plurality of crest portions, and
at least one of the plurality of joint portions is located immediately below the semiconductor element.

### Appendix 5

The semiconductor device according to any one of Appendixes 1 to 4, further comprising:
a circuit pattern which is provided on the upper surface of the heat dissipation base member with an insulating layer interposed between the upper surface and the circuit pattern; and
a terminal which is held by a case that accommodates the semiconductor element and is electrically connected to the semiconductor element,
wherein
the semiconductor element is provided on the circuit pattern,
each of the plurality of heat dissipation fins is joined to the lower surface of the heat dissipation base member at a plurality of joint portions provided between the plurality of crest portions, and
at least one of the plurality of joint portions is located immediately below a joint position between a metal wire joined to the terminal and the circuit pattern or immediately below a joint position between the terminal and the circuit pattern.

### Appendix 6

The semiconductor device according to any one of Appendixes 1 to 5, further comprising a coolant flow path which is provided on the lower surface of the heat dissipation base member so as to include the plurality of heat dissipation fins and through which a coolant for cooling the plurality of heat dissipation fins flows,
wherein the plurality of heat dissipation fins extends in a direction intersecting with a direction in which the coolant flows in the coolant flow path.

### Appendix 7

The semiconductor device according to Appendix 6, further comprising a terminal which is held by a case that accommodates the semiconductor element and is electrically connected to the semiconductor element,
wherein the coolant flows in a direction from a C electrode to a P electrode or an N electrode, each of the C electrode, the P electrode, and the N electrode being provided as the terminal.

### Appendix 8

The semiconductor device according to any one of Appendixes 1 to 7, wherein the heat dissipation base member is joined to a case that accommodates the semiconductor element, and is sealed with a sealing material filled in the case.

### Appendix 9

The semiconductor device according to any one of Appendixes 1 to 8, wherein each of the plurality of crest portions includes two or more constricted portions.

### Appendix 10

The semiconductor device according to any one of Appendixes 1 to 9, wherein
each of the plurality of heat dissipation fins is joined to the lower surface of the heat dissipation base member at a plurality of joint portions provided between the plurality of crest portions, and
the plurality of joint portions has a chevron shape in plan view.

### Appendix 11

The semiconductor device according to any one of Appendixes 1 to 10, further comprising a case which accommodates the semiconductor element and is disposed so as to surround an outer periphery of the heat dissipation base member,
wherein the lower surface of the heat dissipation base member is recessed from a back surface of the case.

### Appendix 12

The semiconductor device according to any one of Appendixes 1 to 11, wherein at least one of two external angles formed by the lower surface of the heat dissipation base member and each of the plurality of crest portions is 90° or more.

### Appendix 13

The semiconductor device according to any one of Appendixes 1 to 12, wherein the semiconductor element includes a wide band gap semiconductor.

While the disclosure has been shown and described in detail, the foregoing description is in all aspects illustrative and not restrictive. It is therefore understood that numerous modifications and variations can be devised.

What is claimed is:

1. A semiconductor device comprising:
a heat dissipation base member which dissipates heat generated in a semiconductor element; and
a plurality of heat dissipation fins which is joined to a lower surface of the heat dissipation base member and is arranged in parallel with each other,
wherein
the semiconductor element is held on an upper surface of the heat dissipation base member,
each of the plurality of heat dissipation fins includes a plurality of crest portions formed by repeatedly bending a band-shaped plate member extending in one direction,
a cross-sectional shape of each of the plurality of heat dissipation fins is distorted due to a left-right asymmetric shape of each of the plurality of crest portions, and
the plurality of crest portions have a sparse region in which an interval between the plurality of crest portions in an extending direction of each of the plurality of heat dissipation fins is sparse and a dense region in which an interval between the plurality of crest portions in the extending direction is denser than the interval in the sparse region.

2. The semiconductor device according to claim 1, wherein among the plurality of heat dissipation fins, a first heat dissipation fin and a second heat dissipation fin are shifted from each other in joint positions with the lower surface of the heat dissipation base member in the extending direction.

3. The semiconductor device according to claim 1, wherein the sparse region and the dense region of the plurality of crest portions are irregularly arranged.

4. The semiconductor device according to claim 1, wherein
each of the plurality of heat dissipation fins is joined to the lower surface of the heat dissipation base member at a plurality of joint portions provided between the plurality of crest portions, and
at least one of the plurality of joint portions is located immediately below the semiconductor element.

5. The semiconductor device according to claim 1, further comprising:
a circuit pattern which is provided on the upper surface of the heat dissipation base member with an insulating layer interposed between the upper surface and the circuit pattern; and
a terminal which is held by a case that accommodates the semiconductor element and is electrically connected to the semiconductor element,
wherein
the semiconductor element is provided on the circuit pattern,
each of the plurality of heat dissipation fins is joined to the lower surface of the heat dissipation base member at a plurality of joint portions provided between the plurality of crest portions, and
at least one of the plurality of joint portions is located immediately below a joint position between a metal wire joined to the terminal and the circuit pattern or immediately below a joint position between the terminal and the circuit pattern.

6. The semiconductor device according to claim 1, further comprising a coolant flow path which is provided on the lower surface of the heat dissipation base member so as to include the plurality of heat dissipation fins and through which a coolant for cooling the plurality of heat dissipation fins flows,
wherein the plurality of heat dissipation fins extends in a direction intersecting with a direction in which the coolant flows in the coolant flow path.

7. The semiconductor device according to claim 6, further comprising a terminal which is held by a case that accommodates the semiconductor element and is electrically connected to the semiconductor element,
wherein the coolant flows in a direction from a C electrode to a P electrode or an N electrode, each of the C electrode, the P electrode, and the N electrode being provided as the terminal.

8. The semiconductor device according to claim 1, wherein the heat dissipation base member is joined to a case that accommodates the semiconductor element, and is sealed with a sealing material filled in the case.

9. The semiconductor device according to claim 1, wherein each of the plurality of crest portions includes two or more constricted portions.

10. The semiconductor device according to claim 1, wherein
each of the plurality of heat dissipation fins is joined to the lower surface of the heat dissipation base member at a plurality of joint portions provided between the plurality of crest portions, and
the plurality of joint portions has a chevron shape in plan view.

11. The semiconductor device according to claim 1, further comprising a case which accommodates the semiconductor element and is disposed so as to surround an outer periphery of the heat dissipation base member,
wherein the lower surface of the heat dissipation base member is recessed from a back surface of the case.

12. The semiconductor device according to claim 1, wherein at least one of two external angles formed by the lower surface of the heat dissipation base member and each of the plurality of crest portions is 90° or more.

13. The semiconductor device according to claim 1, wherein the semiconductor element includes a wide band gap semiconductor.
